(19) United States
(12) Patent Application Publication
(10) Pub. No.: US 2025/0236945 A1
(43) Pub. Date: Jul. 24, 2025

(54) Method of Implanting Atoms in a Substrate and Method of Forming a Quantum Register

(71) Applicants: Universitaet Ulm, Ulm (DE); SaxonQ GMBH, Leipzig (DE)

(72) Inventors: Martin Bodo Plenio, Ulm (DE); Peter Baeuerle, Ulm (DE); Elena Mena Osteritz, Ulm (DE); Franziska Kreuzer, Ulm (DE); Jan Meijer, Leipzig (DE)

(73) Assignees: Universitaet Ulm, Ulm (DE); SaxonQ GMBH, Leipzig (DE)

(21) Appl. No.: 18/705,443

(22) PCT Filed: Oct. 26, 2022
(86) PCT No.: PCT/EP2022/080005

§ 371 Date: Apr. 26, 2024

(30) Foreign Application Priority Data
Oct. 27, 2021 (WO) PCT/EP2021/079846

(51) Int. Cl. C23C 14/12; C23C 14/48

(52) U.S. Cl. CPC C23C 14/12; C23C 14/48

(57) ABSTRACT

A method of implanting atoms into a substrate is disclosed where the atoms are at least some of the constituent atoms of a molecule that has one or more color center atom(s) and one or more satellite atom(s). The molecule may comprise not more than three color center atoms of the same element of the group. The molecule may comprise one or more color center atom(s) other than N, at least six satellite atoms of N, and/or one or more satellite atoms other than ¹³C. A quantum register comprising a color center and at least one nuclear spin isotope atom in a substrate is manufactured using the color center of the quantum register formed by a color center atom implanted into the substrate. A quantum register with such color center and at least one nuclear spin isotope atom in a substrate is disclosed.

### FIELD OF THE INVENTION

The invention relates to methods of implanting atoms into a substrate, wherein the atoms are at least some of the constituent atoms of a molecule. The invention further relates to a method of manufacturing a quantum register, the method making use of the methods of implanting atoms in a substrate. Moreover, the invention relates to a method of manufacturing a quantum information processor, the method making use of the method of manufacturing a quantum register. Also, the invention relates to a quantum register and a use of a molecule.

### BACKGROUND OF THE INVENTION

In “Noise-Resilient Quantum Computing with a Nitrogen-Vacancy Center and Nuclear Spins”, Physical Review Letters, 117, 130502, 2016, J Casanova, Z-Y Wang and M B Plenio present a protocol that achieves a universal set of selective electron-nuclear gates and single nuclear and electronic spin rotations in a quantum register that comprises of ¹³C-nuclei weakly coupled to a nearby nitrogen-vacancy (NV) centre. The authors report that by suppressing inter-nuclear interactions within the register as well as unwanted coupling between the nuclei and the NV centre with other spins within and outside of the register, it becomes possible to achieve quantum gate fidelities well exceeding 99% and selective control of qubits in a quantum register for the purposes of quantum information processing.

In “A Ten-Qubit Solid-State Spin Register with Quantum Memory up to One Minute”, Physical Review X 9, 031045, 2019, and supplementary information, C E Bradley et al report a ten-qubit quantum register consisting of the electron spin of an NV centre and eight ¹³C nuclear spins in diamond. A naturally occurring single NV centre in diamond was used with natural abundance of carbon isotopes. The register exploits the effect that the electron spin continuously couples to all ¹³C spins through the hyperfine interaction and that different nuclear spins can be distinguished by their precession frequencies due to the gradient imposed by the electron spin. The authors report that by generating entanglement between all 45 possible qubit pairs, they were able to show that the register is fully connected. They also report that they were able to realize genuine multipartite entangled states with up to seven qubits.

M H Metsch et al in “Initialization and Readout of Nuclear Spins via a Negatively Charged Silicon-Vacancy Center in Diamond”, Physical Review Letters, 122, 190503, 2019 describe experiments with ingrown silicon vacancy (SiV) centres in a diamond sample. An electron spin polarization of the SiV centre was coherently transferred to the nuclear spin of a ¹³C atom under Hartmann-Hahn conditions, and the nuclear polarization was observed via the fluorescence of the SiV centre.

P Neumann in his dissertation “Towards a room temperature solid state quantum processor—The nitrogen-vacancy center in diamond”, Universität Stuttgart, 2012, describes studies of a quantum register comprised of an NV electron spin and two neighbouring ¹³C nuclear spins. Moreover, the author discloses a method of creating NV centres in an isotopically purified CVD (chemical vapour deposition) diamond by means of nitrogen ion implantation and subsequent annealing. At an implantation energy of 13 MeV per nitrogen ion, 5 to 100 ions were implanted at a depth of around 5 μm.

P. Neumann et al in “Quantum register based on coupled electron spins in a room-temperature solid”, Nature Physics 6, 249, 2010 describe the demonstration of two-qubit quantum gates and entanglement between the electron spins of two distinct NV centres that were separated by 9.8 nm+−0.3 nm as determined by the strong distance dependence of the magnetic dipolar interaction between the electron spins.

In “Triple nitrogen-vacancy centre fabrication by C₅N₄Hₙ ion implantation”, Nature Communications, Nature Communications 10, 2664, 2019, M Haruyama et al describe a method fabricating groups of neighbouring NV centres by means of implanting C₅N₄Hₙ ions. Adenine powder was used and C₅N₄Hₙ ions were implanted at 65 KeV to reach an average depth of 9 nm. The authors report that they were able to fabricate strongly coupled triple NV centres.

WO 2004/059046 A2 discloses a method of producing layers of synthetic monocrystalline diamond by means of CVD. The material can be doped with nitrogen by adding nitrogen to the gas composition in the CVD process. The inventors propose that the diamond be used in a quantum computer that employs NV centres.

Similarly, WO 2010/010352 A1 describes a method of producing a diamond layer by CVD. The inventors suggest that due to the high purity of the diamond layer obtained with their methods, the diamond is particularly suitable for a quantum computer that uses NV centres. The inventors further suggest that nitrogen ion, nitrogen atom or nitrogen containing ion implantation may serve to create an NV centre, and they describe the implantation of nitrogen ions. As an alternative, the inventors suggest growing NV centres into the diamond layer.

From EP 2984499 B1 a method of hyperpolarising ¹³C nuclear spins in a diamond is known. Colour centre electron spins in the diamond are optically pumped, and in a transfer step using a DNP protocol, the polarisation of the spin in the electronic ground state of the colour centre is transferred to the ¹³C nuclear spins in the diamond via a long-range interaction.

### OBJECT OF THE INVENTION

It is an object of the present invention to provide improved methods of implanting atoms into a substrate, wherein the atoms are at least some of the constituent atoms of a molecule. It is a further object of the invention to provide a method of manufacturing a quantum register, the method making use of the methods of implanting atoms in a substrate. Moreover, it is an objective of the present invention to provide a method of manufacturing a quantum information processor, the method making use of the method of manufacturing a quantum register. Also, it is an object of the invention to provide an improved quantum register and an improved molecule.

### SOLUTION ACCORDING TO THE INVENTION

In the following, any reference to one (including the articles “a” and “the”), two or another number of objects is, provided nothing else is expressly mentioned, meant to be understood as not excluding the presence of further such objects in the invention. The reference numerals in the patent claims are not meant to be limiting but merely serve to improve readability of the claims.

According to one aspect of the invention, the problem is solved by a method of implanting atoms into a substrate with the features of claim 1. The atoms are at least some of the constituent atoms of a molecule. The molecule comprises at least one colour centre atom and at least one satellite atom. However, the molecule comprises not more than three colour centre atoms of the same chemical element of the group.

The method includes embodiment in which the molecule as a whole is implanted and remains in the substrate, intact or broke up, as well as methods in which only some of the constituent atoms remain in the substrate.

In the context of the present invention, a “substrate” is a solid material, for example a monocrystal, a polycrystal, or a glass.

In the context of the present invention, a “colour centre atom” is an atom that can form a colour centre in the substrate. A “colour centre” consists of an impurity atom which may (but does not need to) be accompanied by a vacancy in an adjacent lattice site, and which possess optical excitation and absorption bands that lie within the bandgap of the host material and whose electronic ground and/or an electronic excited possess a non-vanishing electronic spin. The word “colour” in “colour centre” is purely for reasons and using conventional terminology and does not imply that a colour centre must evokes a “colour” in any way other than that it possess optical excitation and absorption bands.

Examples for a colour centre are the nitrogen vacancy (NV) centre in diamond, the divacancy centre in 4H—SiC centre in silicon carbide or the T-centre in silicon. For a review of suitable nitrogen vacancy centres in diamond, their properties, manufacture and use see M W Doherty et al, “The nitrogen-vacancy colour centre in diamond”, Physics Reports 528 (1), 1-45, 2013, the relevant content of which is hereby incorporated into the present disclosure by reference. For a review of suitable colour centres in SiC, their properties, manufacture and use see, S Castelletto and A Boretti, “Silicon carbide color centers for quantum applications”, Journal of Physics: Photonics 2 022001, 2020, the relevant content of which is hereby incorporated into the present disclosure by reference. For a review of suitable T centres, their properties, manufacture and use see L Bergeron et al, “Silicon-Integrated Telecommunications Photon-Spin Interface”, PRX Quantum 1, 020301, 2020, the relevant content of which is hereby incorporated into the present disclosure by reference.

In the context of the present invention, a “satellite atom” is an atom that differs from the colour centre atom(s) with regard of its chemical element or at least with regard to its isotope, and which is of a chemical element at least one stable isotope of which chemical element has a non-vanishing nuclear spin, which nuclear spin can interact with the electron spin of the colour centre. This definition does not require that all satellite atoms of a molecule be of the same element, let alone of the same isotope. Yet, as also discussed further below, in some embodiments of the invention satellite molecules are of the same element or even of the same isotope. In the context of the present invention, a stable isotope is an isotope with a lifetime of at least 1000 seconds, more preferably 1 year, more preferably 100 years, more preferably 10 000 years, more preferably a million years.

When implanted into a substrate, the satellite atom can fit a single lattice site of the substrate. In this context, “fit” means that it can fit into the substrate's lattice so that its implantation does not create another colour centre by forcing another vacancy.

It is an achievable advantage of the present invention that—even if the molecule disintegrates upon implantation—the constituent atoms of the molecule that remain in the substrate tend to do so in close proximity of each other. This can be useful in applications, in which such close proximity can be exploited. An example of such application is described in the before-mentioned publication “Noise-Resilient Quantum Computing with a Nitrogen-Vacancy Center and Nuclear Spins”, Physical Review Letters, 117, 130502, 2016 by J Casanova, Z-Y Wang and B Plenio, and in T H Taminiau et al, “Universal control and error correction in multi-qubit spin registers in diamond”, Nature Nanotechnology volume 9, 171-176, 2014, which publication discloses an application for quantum error correction. The relevant content of these publications is hereby incorporated into the present disclosure by reference.

Generally, according to the invention it is not required that all atoms of the molecule are implanted into the substrate. Rather, the invention also encompasses embodiments in which some atoms of the molecule are not implanted into the substrate. In fact, depending on the experimental conditions, only some of the atoms are implanted into the substrate. It is an achievable advantage of limiting the number of colour centre atoms of the same chemical element in the molecule that the likelihood of only one atom of this chemical element being implanted into in the substrate can be improved. The presence of only one colour centre of a particular chemical element, in turn, advantageously can simplify the interaction between a colour centre formed by this atom and satellite atoms such as ¹³C or ²⁹Si atoms originating from the molecule.

According to a further aspect of the invention, the problem is solved by a method of implanting atoms into a substrate with the features of claim 3. The atoms are at least some of the constituent atoms of a molecule. The molecule comprises one or more satellite atom(s), and the molecule comprises one or more colour centre atom(s) other than N (nitrogen). It is an achievable advantage of colour centres atoms other than N that they can give rise to colour centres that are more stable than N-based colour centres, provide a higher optical yield or emit photons in a narrower energy interval.

According to another aspect of the invention, the problem is solved by a method of implanting atoms into a substrate with the features of claim 4. The atoms are at least some of the constituent atoms of a molecule. The molecule comprises one or more N atoms as colour centre atom(s), and the molecule comprises at least 6 satellite atoms. It is an achievable advantage of using N as colour centre atoms in the molecule that appropriate molecules or starting materials for the synthesis of the molecule are more readily available. It is an achievable advantage of a larger number of satellite atoms that after implantation, there is a larger number of atoms near a colour centre originating from a colour enter atom of the molecule that can interact with this colour centre.

According to yet another aspect of the invention, the problem is solved by a method of implanting atoms into a substrate with the features of claim 6. The atoms are at least some of the constituent atoms of a molecule. The molecule comprises one or more colour centre atom(s), and the molecule comprises one or more satellite atoms other than ¹³C (carbon 13), such as ²⁹Si (silicon 29). It is an achievable advantage of the presence of satellite atoms of different elements that the satellite atoms, for example ¹³C and ²⁹Si, have different gyromagnetic ratios and can therefore be distinguished more easily from each other. This can, for example, allow for faster quantum gates.

The skilled person is aware of suitable methods for implantation of the molecule's constituent atoms into a substrate. In this regard, reference is made to “Triple nitrogen-vacancy centre fabrication by C₅N₄Hₙ ion implantation” by M Haruyama et al and T Gaebel et al, “In Room-temperature coherent coupling of single spins in diamond”,

Nature Physics 2, 413, 2006, where it is reported that the implantation of N₂ molecules achieves a pair of NV centres. The relevant content of these publications is herewith incorporated into the present disclosure by reference.

According to a further aspect of the invention, the problem is solved by a method of manufacturing a quantum register with the features of claim 22. The quantum register comprises a combination of at least one colour centre and at least one nuclear spin isotope atom in a substrate. The colour centre of the quantum register is a colour centre formed by a colour centre atom implanted into the substrate according to one of the invention's method of implanting a molecule's constituent atoms into a substrate. Likewise, the nuclear spin isotope atom(s) of the quantum register are nuclear spin isotope atoms(s) implanted into the substrate according to one of the invention's method of implanting atoms into a substrate, and the nuclear spin isotope atoms(s) of the quantum register originate from the same molecule as the colour centre atom forming the colour centre of the quantum register.

In the context of the present invention, “quantum register” means that the at least one nuclear spin isotope atom(s) of the quantum register is/are suitable to be used as qubit(s) in a quantum information processor. A “quantum information processor”, in turn, is a collection of so defined quantum registers that form a device that can perform quantum computations. It is an achievable advantage of the quantum register according to the invention that the nuclear spin isotope atom(s) can act as the qubits of a quantum register and that the electron spin(s) of the colour centre can be used to control these nuclear spin(s) and to achieve quantum gates with the colour centres of a separate quantum register. The skilled person is aware of suitable methods of achieving such control. The relevant disclosure of the before-mentioned publications “Noise-Resilient Quantum Computing with a Nitrogen-Vacancy Center and Nuclear Spins” by J Casanova, Z-Y Wang and B Plenio, “A Ten-Qubit Solid-State Spin Register with Quantum Memory up to One Minute”, Physical Review X 9, 031045, 2019 by C E Bradley et al, “Initialization and Readout of Nuclear Spins via a Negatively Charged Silicon-Vacancy Center in Diamond” by M H Metsch et al, “Towards a room temperature solid state quantum processor—The nitrogen-vacancy center in diamond” by P Neumann as well as T. Gaebel et al, “Room-temperature coherent coupling of single spins in diamond”, Nature Physics 2, 408, 2006, are herewith incorporated into the present disclosure by reference.

In the context of the present invention, a “nuclear spin isotope atom” is a satellite atom that is a “nuclear spin isotope”. A “nuclear spin isotope”, in turn, is an isotope with a non-vanishing nuclear spin. Due to the non-vanishing nuclear spin, the nuclear spin isotope in the substrate can interact, preferably via the hyperfine interaction, with the electron spin of the colour centre.

Generally, according to the invention it is not required that all atoms of the molecule that are implanted into the substrate form part of the quantum register. Rather, the invention also encompasses embodiments in which further atoms may have been implanted which are not considered part of the quantum register.

According to another aspect of the invention, the problem is solved by providing a method of manufacturing a quantum information processor with the features of claim 28. In this method, at least two quantum registers are formed, each according to the invention's method of manufacturing a quantum register. Preferably, the two quantum registers are formed in the same substrate, more preferably at a distance from each other to enables quantum gates via the magnetic dipolar interaction between the electron spins of the colour centres.

According yet another aspect of the present invention, the problem is solved by a quantum register according to claim 29. The quantum register comprises a substrate with a colour centre and at least one nuclear spin isotope atom.

According a final aspect of the present invention, the problem is solved by a use of a molecule that comprises one or more colour centre atom(s) and one or more satellite atom(s) for the manufacture of a quantum register.

A quantum register according to the invention can serve as a local unit of a quantum computer, as a node of a quantum repeater in quantum communication networks, and as a quantum sensor. In these applications, the electronic degree of freedom of the colour centre can serve to control the surrounding nuclear spins, which in turn act as qubits of a quantum memory or resource for quantum error correction to enhance the sensing capabilities of the devices.

With regard to quantum error correction in quantum computation to stabilise quantum information for times that are sufficiently long to execute lengthy quantum algorithms, reference is made to M H Abobeih et al, “Fault-tolerant operation of a logical qubit in a diamond quantum processor”, arXiv 2108.01646, 2021, with regard to quantum error correction in sensing, reference is made to Th Unden et al, “Quantum metrology enhanced by repetitive quantum error correction”, Phys. Rev. Lett. 116, 230502, 2016, with regard to the usefulness of quantum memory, reference is made to S Zaiser et al, “Enhancing quantum sensing sensitivity by a quantum memory”, Nature Communications volume 7, Article number: 12279, 2016, and with regard to the usefulness of auxiliary nuclear spins as intermediate storage of quantum repeaters in quantum communication, reference is made to M Pompili et al, “Realization of a multi-node quantum network of remote solid-state qubits”, 2102.0447, 2021. The relevant content of these publications is hereby incorporated into the present disclosure by reference.

The optical transition of the colour centre can allow its electron spin to be coupled to an optical field and thus achieve quantum communication to other quantum registers. The electron spin can also couple to external magnetic or electric fields or microwave radiation, which can thereby become accessible for detection. A typical quantum register is present in a high-purity diamond, silicon carbide, silicon or other insulator as a substrate. It typically consists of a single optically addressable electron spin in the form of a colour centre and one to 20 nuclear spins isotope atoms, such as ¹³C and/or ²⁹Si, located in the immediate vicinity. In order to reduce or avoid perturbation, typically only very few nuclear spins or paramagnetic impurities that do not belong to the quantum register are located in the vicinity of the quantum register.

### PREFERRED EMBODIMENTS OF THE INVENTION

Preferred features of the invention which may be applied alone or in combination are discussed in the following and in the dependent claims.

In some embodiments of the invention, at least one of the constituent satellite atoms of the molecule is a group IV element, preferably a C or a Si atom. It is an achievable advantage of C and Si that they can fit a single lattice site without creating a vacancy or too strong lattice distortion. Preferably, all satellite atoms of the molecule are of the same chemical element. In some embodiments of the invention, the molecule comprises one or more satellite atoms other than ¹³C, particularly preferably of another element than C. In a preferred such embodiments, all satellite atoms are atoms other than ¹³C, particularly preferably of another element than C.

Preferably, at least one of the constituent satellite atoms is a nuclear spin isotope atom that supports a non-vanishing spin. Advantageously, with this embodiment of the invention it can be exploited that the nuclear spin of the nuclear spin isotope atom can be used as a qubit in a quantum register. The preferred nuclear spin isotope of a C satellite atom is ¹³C. The preferred nuclear spin isotope of a Si satellite atom ²⁹Si. In some preferred embodiments of the invention, all nuclear spin isotope atoms of the molecule are the same isotope. In other preferred embodiments, the molecule has at least two different kinds of nuclear spin isotopes, for example ¹³C and ²⁹Si.

While according to embodiments of the invention, in molecules that comprise more than one satellite atom, all of these satellite atoms of the molecule are nuclear spin isotope atoms, this is not generally required. Rather, the invention also encompasses embodiments in which only some of the molecule's satellite atoms are nuclear spin isotope atoms.

In a preferred method according to the invention, the molecule is chosen—preferably at random—from a sample comprising a multitude of a single species of molecules. The sample may for example be a powder, solution or a suspension of the molecules. Preferably, in the multitude of the molecules the abundance of the nuclear spin isotope is above the natural abundance of this isotope. In other words, in the sample the nuclear spin isotope is enriched above natural abundance. Thereby, advantageously, the number of the nuclear spin isotope atoms implanted can be increased, at least on average. In the context of the present invention, the “natural abundance” of the ¹³C isotope is defined as 1.1% and the “natural abundance” of the ²⁹Si isotope is defined as 4.7%.

Particularly preferably, in the multitude of the molecules the abundance of the nuclear spin isotope is at least twice, particularly preferably at least three times, particularly preferably at least five times the natural abundance of this isotope. Particularly preferably the abundance of the nuclear spin isotope is at least 80%, particularly preferably at least 90%, particularly preferably at least 95%, particularly preferably at least 98%, particularly preferably at least 99%. This can for example be achieved by synthesizing the molecule from nuclear spin isotope-enriched staring materials.

Likewise, advantageously, the number of implanted nuclear spin isotope atoms can be increased by increasing the molecule's number of satellite atoms, all or some of which can be a nuclear spin isotope atom. The preferred molecule comprises between 1 and 20 satellite atoms. The molecule preferably comprises at least 1 satellite atom, particularly preferably at least 2, particularly preferably at least 3, particularly preferably at least 4, particularly preferably at least 5, particularly preferably at least 6, particularly preferably at least 7, 8, 9, 10, 11, 12, 13, 14, 15, 16, 17, 18, 19 or 20 satellite atoms. As a result, in particular of the higher numbers of satellite atoms, a substantial number of nuclear spin isotope atoms can be implanted even at relatively low abundance of the nuclear spin isotope.

In some embodiments of the invention, the preferred molecule comprises at most 90, particularly preferably at most 70 satellite atoms, particularly preferably at most 60, particularly preferably at most 30, particularly preferably at most 20, 19, 18, 17, 16, 15, 14, 13, 12, 11, 10, 9, 8, 7, 6, 5, 4, 3, 2 or even just 1 satellite atom(s), all or some of which can be of a nuclear spin isotope. It is an achievable advantage of a lower number of satellite atoms in the molecule that at a given average number of implanted nuclear spin isotope atoms, the statistical variation in this number of implanted nuclear spin isotope atoms is reduced.

In embodiments where only some of the satellite atoms are nuclear spin isotope atoms as well as in embodiments in which all of the satellite atoms are nuclear spin isotope atoms, the molecule preferably comprises at least 1 nuclear spin isotope atoms, particularly preferably at least 2, particularly preferably at least 3, particularly preferably at least 4, particularly preferably at least 5, particularly preferably at least 6, particularly preferably at least 7, 8, 9, 10, 11, 12, 13, 14, 15, 16, 17, 18, 19 or 20 nuclear spin isotope atoms. It is an achievable advantage of this embodiment of the invention that a larger number of nuclear spin isotope atoms can interact with the colour centre(s).

Also in embodiments where only some of the satellite atoms are nuclear spin isotope atoms as well as in embodiments in which all of the satellite atoms are nuclear spin isotope atoms, the molecule preferably comprises at most 70 nuclear spin isotope atoms, particularly preferably at most 60, particularly preferably at most 30, particularly preferably at most 20, 19, 18, 17, 16, 15, 14, 13, 12, 11, 10, 9, 8, 7, 6, 5, 4, 3, 2 or even just 1 nuclear spin isotope atom(s). It is an achievable advantage of this embodiment of the invention that a smaller number of nuclear spin isotope atoms can reduce or avoid inter-nuclear interactions and mutual perturbation of the interactions of the nuclear spin isotope atoms with the colour centre(s).

A preferred molecule comprises not more than 5 colour centre atoms of the same chemical element (such as, for example, N (nitrogen), Si, Ge (Germanium), Sn (tin), O (oxygen) or Pb (lead)), particularly preferably not more than 4, particularly preferably not more than 3, particularly preferably not more than 2 colour centre atoms of the same chemical element. A particularly preferred molecule comprises only one colour centre atom of the same chemical element. It is an achievable advantage of limiting the number of colour centre atoms of the same chemical element that the likelihood of only one atom of this chemical element being implanted in the substrate can be improved. Thereby, it can be avoided that several colour centres or that a complex colour centre composed of several colour centre atoms of the same element are formed. This, in turn, advantageously can simplify the interaction between a colour centre formed by this atom and other atoms, in particular nuclear spin isotope atoms originating from the molecule. In particular, mutual perturbation of the interaction of the nuclear spin isotope atom with different colour centres, impurities or colour centre atoms that have not formed a colour centre can be reduced or avoided.

A preferred molecule comprises colour centre atoms of only one chemical element. Advantageously, thereby perturbation of the interaction of the nuclear spin isotope atoms with different colour centres of different kinds (ie, originating from different chemical elements) can be reduced or avoided.

Particularly preferably, the molecule comprises not more than 5 colour centre atoms it total, particularly preferably not more than 4, particularly preferably not more than 3, particularly preferably not more than 2 colour centre atoms. A particularly preferred molecule comprises only one colour centre atom. Limiting the number of colour centre atoms can increase the likelihood of only one colour centre atom stopping and remaining in the substrate. Thereby, it can be avoided that several colour centres or that a complex colour centre composed of several colour centre atoms are formed. This, in turn can improve the interaction between a colour centre and other atoms, in particular nuclear spin isotope atoms originating from the molecule. In particular, mutual perturbation of the interaction of the nuclear spin isotope atoms with different colour centres, impurities or colour centre atoms that have not formed a colour centre can be reduced or avoided.

The preferred molecule's colour centre atom(s) is/are selected from a group consisting of the chemical elements N, Si, Ge, Sn, O and Pb. In some embodiments of the invention, the molecule comprises one or more colour centre atom(s) other than N. Preferably in such embodiments, all colour centre atoms are atoms other than N. Preferably, all of the molecule's colour centre atoms are of a different chemical element than any of the molecule's satellite atoms.

The preferred molecule comprises at least one H (hydrogen) atom. This embodiment of the invention can exploit the fact that a bombardment of the substrate with a hydrogen atom can induce the formation of a vacancy in the substrate. This vacancy can preferably combine with a colour centre atom, particularly preferably originating from the same molecule, to form a colour centre. Thus, while it is not necessary for a molecule to contain one or more H atoms, it is an achievable advantage of the presence of hydrogen in the molecule that it can facilitate the formation of a colour centre. Preferably, the molecule comprises at least 2, more preferably at least 10, more preferably at least 20 H atoms. The preferred molecule comprises not more than 100 H atoms, preferably not more than 60, more preferably not more than 40 H atoms. Preferably, the molecule consists exclusively of one or more colour centre atoms, one or more satellite atoms and one or more H atoms.

It is preferred that the atomic mass of at least one, more preferably all, of the colour centre atom(s) of the molecule is between ⅓ and 3 times the atomic mass of at least one, more preferably all, of the nuclear spin isotope atom(s) of the molecule. Thereby, advantageously, it can be achieved that when implanted into the substrate, the atoms stop and remain at similar depths from the surface of the substrate. This, in turn, can increase the proximity of the nuclear spin isotope atoms to the colour centre atom and thus the colour centre in the substrate.

In the molecule, for example the following combinations of one or more colour centre atom(s) and one or more nuclear spin isotope atom(s) are particularly preferred:
Colour centre atom: ¹⁴N or ¹⁵N; nuclear spin isotope atom: ¹³C
Colour centre atom: ¹⁴N or ¹⁵N; nuclear spin isotope atom: ²⁹Si
Colour centre atom: ²⁸Si; nuclear spin isotope atom: ¹³C
Colour centre atom: ²⁸Si; nuclear spin isotope atom: ²⁹Si
Colour centre atom: ⁷⁰Ge, ⁷²Ge, ⁷³Ge or ⁷⁴Ge; nuclear spin isotope atom: ¹³C
Colour centre atom: ⁷⁰Ge, ⁷²Ge, ⁷³Ge or ⁷⁴Ge; nuclear spin isotope atom: ²⁹Si
Colour centre atom: ¹¹⁴Sn, ¹¹⁵Sn, ¹¹⁶Sn, ¹¹⁷Sn, ¹¹⁸Sn, ¹¹⁹Sn or ¹²⁰Sn; nuclear spin isotope atom: ¹³C
Colour centre atom: ¹¹⁴Sn, ¹¹⁵Sn, ¹¹⁶Sn, ¹¹⁷Sn, ¹¹⁸Sn, ¹¹⁹Sn or ¹²⁰Sn; nuclear spin isotope atom: ²⁹Si
Colour centre atom: ²⁰⁶Pb, ²⁰⁷Pb or ²⁰⁸Pb; nuclear spin isotope atom: ¹³C
Colour centre atom: ²⁰⁶Pb, ²⁰⁷Pb or ²⁰⁸Pb; nuclear spin isotope atom: ²⁹Si

In some embodiments of the invention, the molecule is a heterofullerene in which the heteroatom(s) that replaces the C atom(s) in the heterofullerene is/are the colour centre atom(s). Preferred heterofullerenes are those with 20, 60, 70, 72, 74, 76, 78, 80, 82, 84, 86, 88 and 90 atoms, including the C and the other atoms. An example of a suitable heterofullerene is azafullerene (C₅₉NH or (C₅₉N)₂). The heterofulleres can be obtained by the methods disclosed by, eg, F Wudl et al in Science 269, 1554-1556, 1995, by G Zhang in “Progress in the Synthesis and Reaction of Azafullerene”, Chinese Journal of Organic Chemistry 32(6):1010-1023, 2012, by J C Hummelen et al in “; There Is a Hole in My Bucky”, J Am Chem Soc, 117, 26, 7003-7004, 1995, and by J C Hummelen et al in “Isolation of the Heterofullerene C₅₉N as Its Dimer (C₅₉N)₂”, Science, 269, 1554-1556, 1995. The relevant content of these publications is hereby incorporated into the present disclosure by reference.

In some embodiments of the invention, the molecule is a heteroadamantane, in which the heteroatom(s) that replaces the C atom(s) in the heteroadamantane is/are the colour centre atom(s). Example of a suitable heteroadamantane is azaadamantane (C₉H₁₄N) and silaadamantane (C₉H₁₆Si). The heteroadamantanes can be obtained by the method disclosed by Kuznetsov et al in Chem Heterocycl Comp 26, 907-908, 1990, by D A Becker et al in “A Short Synthesis of 1-Azaadamantan-4-one and the 4r and 4s Isomers of 4-Amino-1-azaadamantane”, Synthesis 11, 1992, 1080-1082, and by J Henkel in “General synthesis of N-substituted 2-azaadamantanes and their 4,8-disubstituted derivatives”, J G Henkel, W C Faith and J T Hane, in J. Org. Chem. 46, 1981, 3483-3486. The relevant content of these publications is hereby incorporated into the present disclosure by reference.

In some embodiments of the invention, the molecule is an amine such as triphenylamine (C₁₈H₁₅N). The amines can be obtained by the method disclosed by Rohani et al. in “Synthesis and Analysis of Triphenylamine: A Review”, Can J Chem Engin 82, 323-334, 2004, the relevant content of this publication being hereby incorporated into the present disclosure by reference.

In some embodiments of the invention, the molecule is a silane such as a mono, di-, tri- or tetraphenylsilane, a mono, di-, tri- or tetrakis(phenylethynyl) silane, a mono, di-, tri- or tetrakis((trimethylsilyl)ethynyl) silane, or a mono, di-, tri- or tetraethynylsilane. The silanes can be obtained based on the method disclosed by Z Teng, C Boss and R Keese in Tetrahedron, 53, 1997, 12979-12990 and by F L Geyer, F Rominger and U H F Bunz in Chem—A Eur J 20, 2014, 3600-3605, the relevant content of these publications being hereby incorporated into the present disclosure by reference.

In some embodiments of the invention, the molecule is a germanium such as tetraethynylgermane (C₈H₄Ge), tetraphenylgermane (C₂₄H₂₀Ge). The germanes can be obtained by the method disclosed by D M Harris et al in “Tetraphenylgermane”, T Moeller (Ed): Inorganic Syntheses, Vol 5, McGraw-Hill Inc, 70-72, 1957, the relevant content of this publication being hereby incorporated into the present disclosure by reference.

In some embodiments of the invention, the molecule is a stannane such as tetraphenyltin. The stannanes can be obtained by the method disclosed by L Ellinghaus et al in “Houben-Weyl Methods of Organic Chemistry”, vol. XIII/6, 4th Edition: Organogermanium-and-tin Compounds. Georg Thieme Verlag, 215, 2014 (ISBN 978-3-13-180734-2), the relevant content of this publication being hereby incorporated into the present disclosure by reference.

In some embodiments of the invention, the molecule is a plumbane such as tetraphenylplumbane. The plumbanes can be obtained by the method disclosed by P Truskier et al in “Zur Darstellung organischer Blei- und Quecksilber-Verbindungen”, Chem Ber 37, 1125, 1904, the relevant content of this publication being hereby incorporated into the present disclosure by reference.

Preferably, the molecule is accelerated onto the substrate such that at least some of the constituent atoms of the molecule stop and remain in the substrate so that they are implanted in the substrate. Thus, the substrate is a target which the molecule is accelerated onto. It is preferred that the molecule is an ion. Advantageously, an ion can be accelerated in an electric, magnetic or electromagnetic field.

Preferably, the molecules are present as a solid or as a liquid. In the case of a solid, individual molecules can be extracted using laser ablation. In case of a liquid, the molecules can be extracted using electron spray ionisation. The ionisation of the molecules can be achieved by single or multi-photon ionisation or by field ionisation with suitable voltages. In the case of a liquid, charged molecules can be generated and accelerated by means of Liquid Injection Field Desorption Ionization (LIFD).

In a preferred method, implantation is performed using a Focused Ion Beam (FIB) with electric lenses. Preferably, due to the electric lenses, imaging errors caused by alternating magnetic fields can be reduced. In another preferred method, implantation is performed by methods disclosed in K Groot-Berning, G Jacob, Ch. Osterkamp, F Jelezko and F Schmidt-Kaler, Fabrication of ¹⁵NV-centers in diamond using a deterministic single ion implanter, New J. Phys. 23, 063067 (2021) using a linear Paul trap which traps single ionised molecules are trapped and cooled and then accelerated and focused by electric fields to minimize position errors.

The preferred substrate is an insulator or a semiconductor. Preferably, the substrate's band gap is above 1 eV, more preferably above 3 eV and particularly preferably above 5 eV. A preferred material of the substrate is a crystalline material, for example Si, SiC (silicon carbide) or diamond. It is an achievable advantage of these materials that they are particularly suitable for forming colour centres.

Preferably, the substrate's intrinsic (ie, pre-implantation) ¹³C and/or ²⁹Si concentrations each are less than 10%, more preferably, less than 0.1%, particularly preferably, less than 0.01% and even more preferably less than 1 ppm (parts per million) (ppm), more preferably less than 1 ppb (parts per billion). Thereby, advantageously, interference coupling of the nuclear spins of such atoms with the colour centre(s) and/or the nuclear spin isotope atoms can be reduced substantially. As to suitable method for achieving and measuring such concentrations, reference is made to the publications by P Neumann et al in Nature Physics 6, 249, 2010, where it is mentioned that by using isotopically purified CH₄ gas in the CVD growth process they have achieved 99.99% purity of ¹²C, by T Teraji in “Chemical Vapor Deposition of ¹²C Isotopically Enriched Polycrystalline Diamond”, Japanese Journal of Applied Physics 51, 090104, 2012, where 99.997% ¹²C purity and a nitrogen content of 4 ppb was achieved, and by E D Herbschleb et al in “Ultra-long coherence times amongst room-temperature solid-state spins”, Nature Communications 10, 3766, 2019 where diamond was produced from 99.998% enriched CH₄ in CVD growth yielding this purity in the grown diamond. The relevant content of these publications are hereby incorporated into the present disclosure by reference.

The substrate's intrinsic (ie, pre-implantation) concentration of paramagnetic defects preferably is less than 1 ppm, more preferably less than 10 ppb, more preferably less than 1 ppb and even more preferably 0.1 ppb. Thereby, advantageously, perturbation caused by the interaction of such defects with the colour centre(s) and/or the nuclear spin isotope atoms can be avoided. It is an achievable advantage of reducing paramagnetic defects in the vicinity of the quantum register that decoherence can be reduced. M J Degen et al in Sections 5 and 13 of the Supplementary Information for “Entanglement of dark electron-nuclear spin defects in diamond”, Nat Commun 12, 3470, 2021, explain how the density of the paramagnetic centres can be estimated based on de-coherence of NV electron spins. Ti Teraji et al in “Chemical Vapor Deposition of ¹²C Isotopically Enriched Polycrystalline Diamond”, Japanese Journal of Applied Physics 51, 090104, 2012, disclose how paramagnetic centres such as P1 centres, ie, nitrogen that has not formed a nitrogen vacancy centre, can be measured, eg, by electron spin resonance for concentrations between 0.1 ppb and 1 ppm, see in particular the right column on page 5 of the publication. The relevant content of these publications is hereby incorporated into the present disclosure by reference.

The preferred substrate contains sulphur at a concentration of above 10¹⁸ atoms/cm³, preferably above, more preferably above 10¹⁹ atoms/cm³. The preferred sulphur concentration in the substrate is below 10²² atoms/cm³ more preferably below 10²¹ atoms/cm³, more preferably below 10²⁰ atoms/cm³. Advantageously, the presence of traces of sulphur in the substrate increases the conversion of colour centre atoms in the substrate to colour centres. A substrate with traces of sulphur in such amount can be obtained for example with the method described in DE 102019117423 A1, and the relevant content of this publication is hereby incorporated into the present disclosure by reference.

In a preferred method, at least one of the implanted colour centre atom(s) of the molecule forms a colour centre in the substrate. Preferably, the formation of the colour centre is induced by annealing, for example as described in section 2.2.2 of the before-mentioned dissertation “Towards a room temperature solid state quantum processor—The nitrogen-vacancy centre in diamond” by P Neumann with regard to a nitrogen vacancy (NV) centre or by J M Smith*, Simon A. Meynell, Ania C. Bleszynski Jayich and Jan Meijer in “Colour centre generation in diamond for quantum Technologies”, Nanophotonics 8(11): 1889-1906, 2019. The skilled person can adapt this annealing method to other types of colour centres in other substrates. The annealing method can exploit that vacancies present in the substrate tend to migrate towards colour centre atoms, thereby forming colour centres. The relevant content of section 2.2.2 of the dissertation is hereby incorporated into the present disclosure by reference.

A preferred quantum register comprises a colour centre and at least one nuclear spin isotope atom in a substrate. The colour centre of the quantum register preferably is formed by a colour centre atom implanted into the substrate with a method according to the present invention. Similarly, the nuclear spin isotope atom(s) of the quantum register are implanted into the substrate with a method according to the present invention. Preferably, the nuclear spin isotope atom(s) of the quantum register originate from the same molecule as the colour centre atom forming the colour centre of the quantum register.

In a preferred quantum register, each nuclear spin isotope atom of the quantum register is located at a distance of less than 2 nm (nanometres) from the colour centre, preferably at a distance of less than 1.5 nm, more preferably less than 1 nm, more preferably less than 0.75 nm from the colour centre. Thereby, advantageously, a reliable interaction between the nuclear spin isotope atom and the colour centre can be achieved. This can be achieved for example by producing several quantum registers and then, based on measuring the distance between the nuclear spin isotope atom(s) and the colour centre(s), selecting those quantum registers that fulfil the above requirement. A suitable method of measuring the distance between a colour centre and a nuclear spin isotope atom is disclosed in P. Neumann et al in “Quantum register based on coupled electron spins in a room-temperature solid”, Nature Physics 6, 249, 2010, and the relevant content of this publication is hereby incorporated into the present disclosure by reference.

In a preferred quantum register, the distance between each pair of the nuclear spin isotope atoms of the quantum register is more than 0.1 nm, preferably more than 0.2 nm, more preferably more than 0.3 nm, more preferably more than 0.5 nm, more preferably more than 1 nm. It is an achievable advantage of ensuring a minimum distance between the nuclear spin isotope atoms that mutual perturbation of their individual interactions with the colour centre can be reduced or avoided. This can be achieved for example by producing several quantum registers and then, based on measuring the distance between the nuclear spin isotope atoms, selecting those quantum registers that fulfil the above requirement. A suitable method of measuring the distance between nuclear spin isotope atoms is disclosed in P. Neumann et al in “Quantum register based on coupled electron spins in a room-temperature solid”, Nature Physics 6, 249, 2010, and the relevant content of this publication is hereby incorporated into the present disclosure by reference.

In the substrate, preferably any nuclear spin isotope atom that is not part of the quantum register but is the same chemical element and isotope as a nuclear spin isotope atom of the quantum register is at a distance of at least 2.5 nm from the quantum register's colour centre, more preferably at least 5 nm, more preferably at least 7.5 nm, more preferably at least 10 nm from the quantum register's colour centre. Thereby, advantageously, perturbation caused by the interaction of the nuclear spins of such atoms with the colour centre(s) and the nuclear spin isotope atoms can be avoided. Particularly preferably, any nuclear spin isotope atom that is not part of the quantum register—regardless of its chemical element and isotope—is at a distance of at least 2.5 nm from the quantum register's colour centre and the satellites, more preferably at least 5 nm, more preferably at least 7.5 nm, more preferably at least 10 nm from the quantum register's colour centre. Thereby, advantageously, perturbation caused by the interaction of the nuclear spins of such atoms with the colour centre(s) and the nuclear spin isotope atoms can be avoided. In the context of the present invention, a “nuclear spin isotope atom that is not part of the quantum register” is an atom of an element and isotope that can interact with the electron spin of the colour centre and the nuclear spin isotope atoms of the quantum register provided that it is sufficiently close to this colour centre and the register.

In the substrate, preferably there is no colour centre that is not part of a quantum register but is of the same kind as a colour centre of the quantum register at a distance of less than 10 nm from any colour centre of the quantum register, more preferably less than 25 nm, more preferably less than 50 nm, more preferably less than 100 nm from any colour centre of the quantum register. In the context of the present invention, colour centres are of the “same kind” if their respective colour centres' atom is of the same chemical element.

More preferably, in the substrate there is no colour centre that is not part of a quantum register—regardless of the kind of colour centre—at a distance of less than 10 nm from any colour centre of the quantum register, more preferably less than 25 nm, more preferably less than 50 nm, more preferably less than 100 nm from any colour centre of the quantum register. Particularly preferably, there is no paramagnetic defect—regardless of its kind—in the substrate at a distance of less than 5 nm from any colour centre of the quantum register, even more preferably at a distance of less than 7 nm, more preferably less than 10 nm from any colour centre of the quantum register.

In the substrate, preferably the colour centre of the quantum register is at a depth of less than 100 nm from a surface of the substrate, preferably less than 50 nm, more preferably less than 20 nm from a surface of the substrate. The depth at which the constituent atoms of the molecule are implanted into the substrate is a function of the energy to which the molecule is accelerated. Accordingly, the depth of the constituent atoms generally increases with the energy with which the molecule is accelerated. Moreover, the momentum of the molecule is split up between the constituent atoms roughly as a function of their mass. For this reason, the depth of the atoms is also a function of their mass. In other words, atoms of different mass end up at different depths. A theoretical discussion of this effect is provided by J Lindhard et al in “Range Concepts and Heavy Ion Ranges (Notes on Atomic Collisions II)”, Mat Fys Medd Dan Vid Selsk 33, no. 14, 1963. The numerical tool SRIM (Stopping Range of Ions in Matter) provided by the author, James F Ziegler, United States Naval Academy, Annapolis on his website “www.srim.org” can be used to predict penetration depths. The graphs provided in the publication by Lindhard et al reveal that, very roughly, the relationship between depth d, kinetic energy E and mass m of the constituent atoms is as follows

$$d ∼ \frac{E}{m}$$

Accordingly, implanting the atoms closer to the surface—by using a lower energy—can entail that atom of different masses stop and remain at similar depths and thus closer to each other. This can be of particular advantage if the colour centre atom(s) and the nuclear spin isotope atoms considerably differ in atomic mass.

By implanting multiple molecules into the same substrate, multiple quantum registers can be realised in the same substrate. Preferably 2 or more, more preferably more than 9, more preferably more than 100, even more preferably more than 10 000, even more preferably more than 1 million quantum registers are formed in the same substrate with a method according to the present invention.

In a preferred substrate that contains more than one quantum register, the distance between at least two of these quantum registers, more preferably between any pair of these quantum registers, is greater than 5 nm, preferably greater than 7 nm, more preferably greater than 10 nm. In a preferred substrate that contains more than one quantum register, the distance between at least two of these quantum registers, more preferably between any pair of these quantum registers is smaller than 300 nm, more preferably smaller than 100 nm, more preferably smaller than 30 nm.

The methods and the quantum register of the present invention can be scaled to a quantum computer as for example described in the publication by P Neumann et al in “Quantum register based on coupled electron spins in a room-temperature solid” cited further above.

### Detailed Description of Embodiments of the Invention

In the following, further preferred embodiments of invention are illustrated by means of examples. The invention is not limited to these examples, however.

### Manufacture of Tetraphenylsilane (First Method)

For the manufacture of tetraphenylsilane UU-01 (C₂₄H₂₀Si) according to a first method,

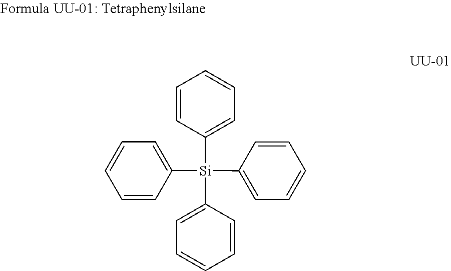 [SMILES: c1ccc([Si](c2ccccc2)(c2ccccc2)c2ccccc2)cc1]

commercially available tetraphenylsilane (purity 96%) with a natural abundance of the ¹³C isotope was used as a starting material. First, tetraphenylsilane UU-01 was purified by column chromatography (silica, petroleum ether (PE)/dichloromethane (DCM) 9:1), whereby a by-product could be separated. Subsequently, 500 mg of tetraphenylsilane UU-01 were sublimed at a vacuum of 5·10⁻¹ mbar and at a temperature of 200° C. After one day, about 50 mg could be removed from the sublimation finger. The purity of this compound was then determined by GC-FID and a purity greater than 99.7% was obtained.

### Manufacture of Tetraphenylsilane (Second Method)

For the manufacture of tetraphenylsilane UU-01 according to a second method, bromobenzene with a natural abundance of the ¹³C isotope was lithiated with n-butyl lithium (n-BuLi) and the lithiated species was then mixed with silicon tetrachloride:

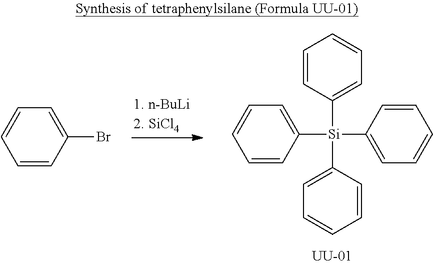 [SMILES: Brc1ccccc1 ; c1ccc([Si](c2ccccc2)(c2ccccc2)c2ccccc2)cc1]

The purity of the compound was confirmed by NMR, GC-MS, and GC.

More specifically, to a solution of bromobenzene (0.1 mL, 0.96 mmol) and 0.7 mL of dry diethyl ether was added n-BuLi (1.6 M, 0.57 mL, 0.96 mmol) at −78° C. and then stirred at room temperature for one hour. The reaction solution was again brought to −78° C. and 0.2 mL of a stock solution (0.2 mL, 0.16 mmol) consisting of 3 mL dry diethyl ether and 0.3 mL (2.58 mmol) silicon tetrachloride was added. The reaction was then heated to 30° C. for 4 hours. Dichloromethane was added to the resulting suspension and filtered. The filter cake was washed with 10 mL dichloromethane and discarded. The mother liquor was concentrated and the solid obtained was purified by column chromatography (silica, PE/DCM 8:1). The solid obtained was then dissolved in DCM and precipitated with n-hexane. Tetraphenylsilane UU-01 (49 mg, 0.14 mmol) was isolated as a colourless solid in a yield of 88%.

The analysis of the material thus obtained yielded the following results: ¹H-NMR (400 MHz, CDCl₃, 20° C.): δ=7.65-7.52 (m, 8H), 7.48-7.32 (m, 12H) ppm. ¹³C-NMR (125 MHz, CDCl₃, 20° C.): δ=136.54, 134.33, 129.73, 128.01 ppm.

### Manufacture of Tetrakis(Phenylethynyl) Silane

Tetrakis(phenylethynyl) silane UU-02 (C₃₂H₂₀Si) was manufactured analogously to the method by Z Teng, C Boss and R Keese, Tetrahedron, 53, 1997, 12979-12990; the relevant content of this publication is incorporated into the present disclosure by reference. Phenylacetylene was lithiated with n-BuLi and the lithiated species was then mixed with silicontetrachloride:

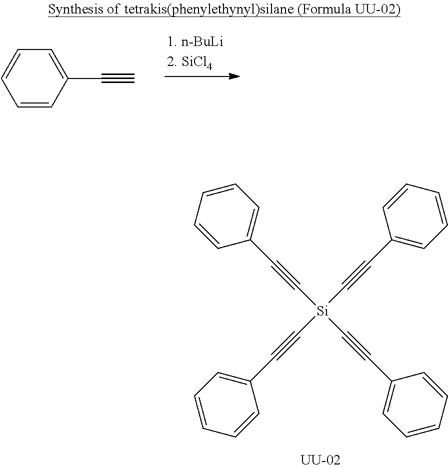

After aqueous work-up, the solid obtained was re-crystallised twice from toluene. Tetrakis(phenylethynyl) silane UU-02 was obtained in a yield of 60%. The purity of the compound was confirmed by NMR, GC-MS, and GC.

More specifically, n-BuLi (1.6 M, 6.2 mL, 10 mmol) was placed in 10 mL dry THF at −78° C., and phenylacetylene (1.1 mL, 10 mmol) with a natural abundance of the ¹³C isotope was slowly added. The reaction solution was then stirred at 0° C. for one hour and then tetrachlorosilane (0.25 mL, 2.3 mmol) was added at −78° C. Then the reaction solution was slowly heated to room temperature overnight and heated at 60° C. for two hours. After the reaction solution had cooled down, water was added and the mixture was extracted twice with diethyl ether (20 mL). The combined organic phases were dried with magnesium sulphate and then concentrated to dryness on a rotary evaporator. The solid obtained was then re-crystallised twice from toluene. (Note: recrystallisation requires very little toluene, n-hexane was used for further re-crystallisation). Tetrakis(phenylethynyl) silane UU-02 (586 mg, 1.36 mmol) was isolated in a yield of 60%.

The analysis of the material thus obtained yielded the following results: ¹H-NMR (400 MHz, CDCl₃, 20° C.): δ=7.68-7.59 (m, 8H), 7.40-7.31 (m, 12H) ppm. ¹³C-NMR (125 MHz, CDCl₃, 20° C.): δ=132.65, 129.66, 128.41, 122.09, 106.75, 86.11 ppm.

### Manufacture of Tetrakis((Trimethylsilyl)Ethynyl)Silane

Tetrakis[(trimethylsilyl)ethynyl]silane UU-03 (C₂₀H₃₂Si₄) was manufactured analogously to the method by F L Geyer, F Rominger and U H F Bunz, Chem-A Eur J, 20, 2014, 3600-3605; the relevant content of this publication is incorporated into the present disclosure by reference. Trimethylsilylacetylene with a natural abundance of the ¹³C isotope was lithiated with n-BuLi and then reacted with tetrachlorosilane:

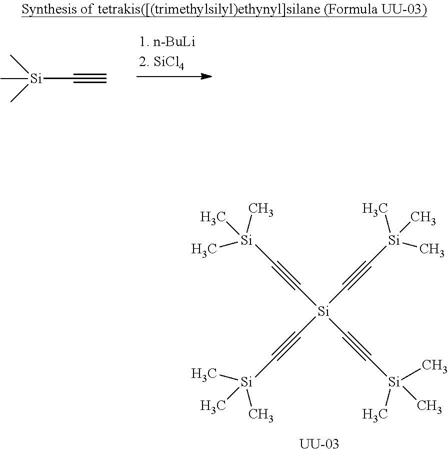

After an aqueous work-up, tetrakis[(trimethylsilyl)ethynyl]silane UU-03 was purified by double recrystallisation from n-hexane. The purity was also confirmed by NMR, GC-MS, and GC.

More specifically, trimethylsilylacetylene (30 mL, 212 mmol) was dissolved in 300 mL dry diethyl ether and brought to 0° C. Then 135 mL n-BuLi (1.6 M, 212 mmol) was added dropwise via a transfer cannula and stirred at 0° C. for another 15 min. Then a solution of silicon tetrachloride (9.0 mL, 53 mmol) and 300 mL dry diethyl ether cooled to 0° C. was added dropwise via a transfer cannula. The reaction solution reached room temperature overnight by slowly warming it in an ice bath. Then 200 ml of water was added and the aqueous phase was extracted twice with diethyl ether. The combined organic phases were dried with magnesium sulphate and the solid obtained was recrystallised from n-hexane. Tetrakis[(trimethylsilyl)ethynyl]silane UU-03 (15.4 g, 36.9 mmol) was obtained as a colourless solid in a yield of 70%.

The analysis of the material thus obtained yielded the following results: ¹H-NMR (400 MHz, CDCl₃, 20° C.): δ=0.21 (s, 36H) ppm. ¹³C-NMR (125 MHz, CDCl₃, 20° C.): δ=117.10, 104.00-0.41 ppm.

### Manufacture of Tetraethynylsilane

Tetraethynylsilane UU-04 (C₈H₄Si) was manufactured analogously to the method by F. L. Geyer and F. Rominger, U H F Bunz, Chem—A Eur J, 20, 2014, 3600-3605; the relevant content of this publication is incorporated into the present disclosure by reference. Tetrakis[trimethylsilyl)ethynyl]silan UU-03 as obtained in the previous example was used as a starting material:

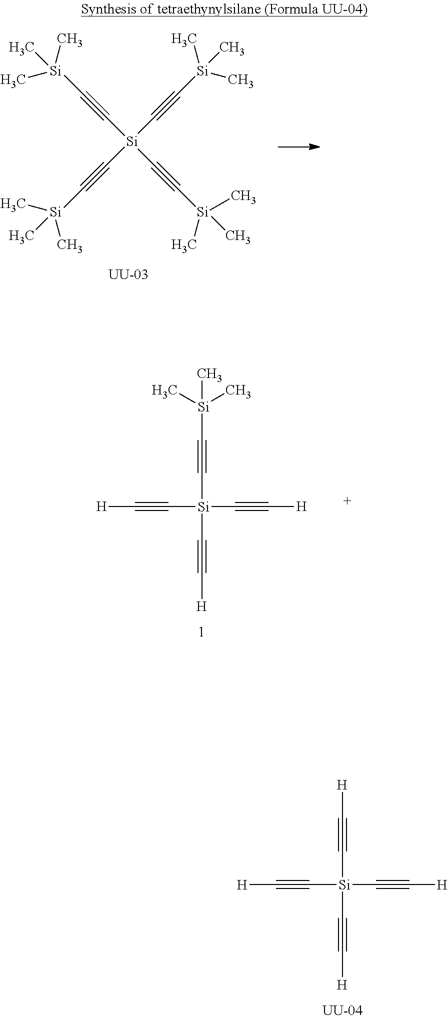

The purity was also confirmed by NMR, GC-MS, and GC.

More specifically, tetrakis[(trimethylsilyl)ethynyl]silane UU-03 (5.1 g, 12 mmol) was dissolved in dry n-pentane under argon. Trifluoromethanesulfonic acid (4.4 mL, 50 mmol) was then added all at once and stirred overnight. The reaction progress was checked by GC-MS, and when singly protected triethynyl[(trimethylsilyl)ethynyl]silane was still present according to GC-MS, another drop of trifluoromethanesulfonic acid was added and stirred for another 2 hours. Afterwards, a reaction control was carried out again by means of GC-MS. A total of 3 drops of trifluoromethanesulfonic acid had to be added until no singly protected triethynyl[(trimethylsilyl)ethynyl]silane was detectable by GC-MS. Then 100 mL demineralised water were added and the sample was shaken in a shaking funnel until the brown colour of the organic phase disappeared completely. The aqueous phase was then extracted twice with 100 mL of pentane each time. The combined organic phases were dried with magnesium sulphate. The solvent was then carefully distilled off on a rotary evaporator (40° C. bath temperature, 600 mbar) until solids began to precipitate. For precipitation, the solution was kept overnight in a −32° C. refrigerator. The next day at −78° C. the supernatant n-pentane was removed using a syringe fitted with a syringe filter and the residue was washed twice at −78° C. with pre-cooled n-pentane at 10 mL each. Then the residue was thawed in a closed vessel and the remaining n-pentane was carefully blown out with argon. Tetraethynylsilane UU-04 (0.9 g, 7 mmol, 57%) was obtained as a colourless solid in a yield of 57%. To further purify the obtained tetraethynylsilane UU-04, a sublimation was carried out at 60° C. under normal pressure overnight.

The analysis of the material thus obtained yielded the following results: ¹H-NMR (400 MHz, CDCl₃, 20° C.): δ=2.66 (s, 4H) ppm. ¹³C-NMR (125 MHz, CDCl₃, 20° C.): δ=96.37, 80.32 ppm.

### Manufacture of ¹³C-Tetraphenylsilane

¹³C-labelled tetraphenylsilane UU-05 (¹³C₂₄H₂₀Si) was manufactured in an analogous fashion to the manufacture of conventional tetraphenylsilane UU-01 according to a second method described above but with ¹³C-bromobenzene as a starting material:

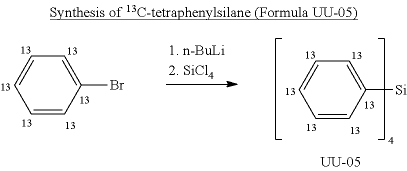

The purity was also confirmed by NMR, GC-MS, and GC.

More specifically, to a solution of ¹³C-bromobenzene (0.1 mL, 0.91 mmol) and 0.7 mL dry diethyl ether was added n-BuLi (1.6 M, 0.54 mL, 0.91 mmol) at −78° C. and then stirred at room temperature for one hour. The reaction solution was again brought to −78° C. and part of a silicon tetrachloride solution (0.2 mL, 0.16 mmol) consisting of 3 mL dry diethyl ether and 0.3 mL (2.58 mmol) silicon tetrachloride was added. The reaction was then heated to 30° C. for 4 hours. Dichloromethane was added to the resulting suspension and filtered. The filter cake was washed with 10 mL dichloromethane and then discarded. The mother liquor was concentrated and the solid obtained was purified by column chromatography (silica, PE/DCM 8:1). The solid obtained was then dissolved in DCM and precipitated with n-hexane. ¹³C-Tetraphenylsilane UU-05 (48 mg, 0.13 mmol) was isolated as a colourless solid in a yield of 81%.

The analysis of the material thus obtained yielded the following results: ¹H-NMR (400 MHz, CD₂Cl₂, 20° C.): δ=7.82-7.50 (m, 8H), 7.45-7.13 (m, 12H) ppm. ¹³C-NMR (125 MHz, CD₂Cl₂, 20° C.): δ=137.94-135.76 (m), 135.51-133.27 (m), 131.15-129.27 (m), 129.27-126.72 (m) ppm.

### Ion Implantation

A molecule of aniline (N₁C₆H₇) comprising one ¹⁴N atom, six ¹³C atoms and seven ¹H atoms is implanted into a high-purity diamond substrate by means of the electrostatic accelerator.

Aniline with a fraction of 50% of the C atoms being ¹³C isotopes is available from Sigma Alderich, Burlington, MA, United States. 20 mg of liquid Aniline is introduced into a cathode and ionised and negatively charged by sputtering with Cs (cesium) atoms.

The negatively charged molecule are extracted by means of an electrostatic potential of 20 KV in vacuum and accelerated in the tube of the accelerating with an electrostatic potential of 80 KV to a total of 100 KeV kinetic energy. Additional ions or fragments are separated by means of a magnetic field as for example described by T Luhmann, N Raatz, R John et al in “Screening and engineering of colour centres in diamond”, Journal of Physics D: Applied Physics 51 (48), 2018, 483002. This molecule is then shot onto the surface of a high-purity diamond. The diamond purchased from Element Six, 1 Debid Road, Nuffield Springs, 1559 Gauteng, UK and doped with sulphur at a concentration of 2.5·10¹⁸ ions/cm³ as described by T Lühmann, R John, R Wunderlich, J Meijer, S Pezzagna in “Coulomb-driven single defect engineering for scalable qubits and spin sensors in diamond”, Nature communications 10 (1), 2019, 1-9.

It is believed that the impact breaks up the molecule, but that the ¹³C and ¹⁴N atoms have the same energy per nucleon (1 KeV/n) and thus about the same range of 20 nanometres each. The atoms then have a distance of only 4 to 5 nanometres so that quantum mechanical coupling is possible. At an implantation energy of 50 KeV, the numbers are halved.

The features as described in the above description, claims and figures can be relevant individually or in any combination to realise the various embodiments of the invention.

1. A method of implanting atoms into a substrate, wherein the atoms are at least some of the constituent atoms of a molecule and wherein the molecule comprises one or more color center atom(s) and one or more satellite atom(s), wherein the molecule comprises not more than three color center atoms of the same element of the group.

2. The method according to claim 1, wherein the color center atom(s) is/are selected from a group consisting of the elements N, Si, Ge, Sn, O and Pb.

3. A method of implanting atoms into a substrate, wherein the atoms are at least some of the constituent atoms of a molecule and wherein the molecule comprises one or more satellite atom(s), wherein the molecule comprises one or more color center atom(s) other than N.

4. A method of implanting atoms into a substrate, wherein the atoms are at least some of the constituent atoms of a molecule and wherein the molecule comprises one or more N atoms as color center atom(s), wherein the molecule comprises at least 6 satellite atoms.

5. The method according to claim 1, wherein the molecule's satellite atom or at least one of the molecule's satellite atoms is a C or a Si silicon atom.

6. A method of implanting atoms into a substrate, wherein the atoms are at least some of the constituent atoms of a molecule and wherein the molecule comprises one or more color center atom(s), wherein the molecule comprises one or more satellite atoms other than ¹³C.

7. The method according to claim 1, wherein the satellite atom or at least one of the molecule's nuclear spin atoms is a nuclear spin isotope atom.

8. The method according to claim 1, wherein the molecule is chosen at random from a sample comprising a multitude of the molecules, wherein in the multitude of the molecules the abundance of the nuclear spin isotope is at least twice its natural abundance.

9. The method according to claim 1, wherein the molecule comprises at least four satellite atoms.

10. The method according to claim 1, wherein the molecule comprises less than ninety satellite atoms.

11. The method according to claim 1, wherein the molecule further comprises at least four satellite atoms of a nuclear spin isotope.

12. The method according to claim 1, wherein the molecule comprises exactly one color center atom and/or at least one H atom.

13. (canceled)

14. The method according to claim 1, wherein the atomic mass of at least one color center atom of the molecule is between ⅓ and 3 times the atomic mass of at least one nuclear spin isotope atom of the molecule.

15. The method according to claim 1, wherein the molecule is selected from a group consisting of heterofullerenes, heteroadamantanes, amines, silans, germans, stannanes and plumbanes.

16. The method according to claim 1, wherein the molecule is an ion and is accelerated onto the substrate such that at least some of the constituent atoms of the molecule stop and remain in the substrate so that they are implanted in the substrate.

17. The method according to claim 1, wherein the substrate comprises diamond, Si or SiC.

18. The method according to claim 1, wherein the substrate's ¹³C and ²⁹Si concentrations each are less than 10% and/or the substrate contains paramagnetic defects at a concentration of less than 10 ppm.

19. (canceled)

20. The method according to claim 1, wherein the substrate contains sulphur at a concentration of above 10¹⁸/cm³.

21. The method according to claim 1, wherein at least one of the implanted colour centre color center atom(s) of the molecule forms a color center in the substrate.

22. A method of manufacturing a quantum register comprising a color center and at least one nuclear spin isotope atom in a substrate, wherein the color center of the quantum register is a color center formed by a color center atom implanted into the substrate according to the method of claim 21 and the nuclear spin isotope atoms(s) of the quantum register are nuclear spin isotope atoms(s) implanted into the substrate according the method of claim 1, wherein the nuclear spin isotope atom(s) of the quantum register originate from the same molecule as the color center atom forming the color center of the quantum register.

23. The method according to claim 22, wherein each nuclear spin isotope atom of the quantum register is located at a distance of less than 2 nm from any of the quantum register's color center(s).

24. The method according to claim 22, wherein the distance between each pair of the nuclear spin isotope atoms of the quantum register is more than 0.1 nm.

25. The method according to claim 22, wherein any nuclear spin isotope atom that is not part of the quantum register is at a distance of at least 2.5 nm from any of the quantum register's color center(s).

26. The method according to claim 22, wherein there is no paramagnetic defect that is not part of the quantum register in the substrate at a distance of less than 25 nm from the color center of the quantum register.

27. The method according to claim 22, wherein the color center of the quantum register is at a depth of less than 100 nm from a surface of the substrate.

28. A method of manufacturing a quantum information processor wherein at least two quantum registers are formed, each according to the method of claim 22.

29. A quantum register comprising a color center and at least one nuclear spin isotope atom in a substrate.

30. A process for manufacturing a quantum register using a molecule that comprises one or more color center atom(s) and one or more satellite atom(s).
